(19) United States
(12) Patent Application Publication
(10) Pub. No.: US 2015/0306701 A1
(43) Pub. Date: Oct. 29, 2015

(54) METHOD AND APPARATUS FOR CONNECTING CONNECTION ELEMENTS TO THE SUBSTRATE OF A POWER SEMICONDUCTOR MODULE BY WELDING

(71) Applicant: Semikron Elektronik GmbH & Co. KG, Nurnberg (DE)

(72) Inventors: Björn TAUSCHER, Abendberg (DE); Stefan FRIES, Nurnberg (DE)

(21) Appl. No.: 14/675,315

(22) Filed: Mar. 31, 2015

(30) Foreign Application Priority Data
Mar. 31, 2014 (DE) 10 2014 104 496.7

(51) Int. Cl. B23K 20/10; H01L 23/00; B23K 20/00

(52) U.S. Cl. CPC B23K 20/106; B23K 20/002; H01L 24/75; H01L 24/83; H01L 2224/83205; H01L 2224/29147; H01L 2224/32225; H01L 2224/838; H01L 2224/75343

(57) ABSTRACT

Apparatus and method for connecting a connection element of a power semiconductor module to a conductor track by welding. The apparatus includes an abutment for the arrangement of the substrate. The abutment has first and second partial abutments. The first partial abutment is a metal shaped body with a modulus of elasticity of between 50 and 300 kN/mm², and the second partial abutment is an elastic shaped body with a modulus of elasticity of between 10 and 500 N/mm². A bottom element rests on the second partial abutment. The apparatus further includes a holding device to fix the bottom element on the abutment; a sonotrode; and a positioning device for positioning the connection element in relation to the substrate.

### BACKGROUND OF THE INVENTION

1. Field of the Invention

The invention relates to apparatus and method for connecting connection elements to a substrate, in particular to a conductor track of the substrate of a power semiconductor module, by welding.

2. Description of the Related Art

As used herein, the term “connection by welding”, or “welded connection” for short, is intended to mean any type of welded connection, but, in particular, an ultrasonically welded connection and related types of connection, but explicitly excluding a wire bonding connection, as is customary in the art as thin- or thick-wire bonding connections.

The prior art discloses, by way of example in German Patent Application Ser. No. DE 101 03 084 A1, a power semiconductor module having at least one power semiconductor component. In this device, the power semiconductor component is arranged directly on a substrate which has an insulating-material body and a metal layer which is arranged on the top face, which faces the power semiconductor component, and is fixedly connected to the insulating-material body. At least one connection element of the power semiconductor module is welded to the metal layer.

A embodiment, which is customary in the art, of an apparatus for connecting connection elements to conductor tracks of a substrate by welding has a metal abutment for the arrangement of a bottom element which can be in the form of a base plate with a substrate located on it or can be in the form only of a substrate, has a holding device which is designed to fix the bottom element on the abutment, and also has a sonotrode. In addition, a positioning device for positioning the connection element in relation to the substrate can be provided.

A fundamental problem with such devices, however, is that when a welded connection is provided by means of an apparatus which is customary in the art, the connection between the metal layer, which forms conductor tracks in a manner customary in the art, and the insulating-material body is preliminarily damaged or damaged by the introduction of the ultrasonic welding energy from the sonotrode onto the connection element. In the process, this connection between the insulating-material body and the conductor track may become detached, at least locally, when the power semiconductor module is used. As a result, at least the durability of the power semiconductor module may be limited.

There is thus a need in the art for an improved method and apparatus for welding a connection element to conductor tracks on a power semiconductor module.

### SUMMARY OF THE INVENTION

The object of the invention is to provide an improved method and apparatus for ultrasonically welding a connection element to a power semiconductor module.

The inventive apparatus comprises: an abutment for the arrangement of a bottom element which is in the form of a substrate or in the form of a base plate with a substrate located on it. The abutment has first and second partial abutments, wherein the first partial abutment is a metal shaped body with a modulus of elasticity of between 50 and 300 kN/mm², and the second partial abutment is an elastic shaped body with a modulus of elasticity of between 10 and 500 N/mm². The bottom element rests on the second partial abutment, in particular exclusively on the second partial abutment. The apparatus further comprises: a holding device which is designed to fix the bottom element on the abutment; a sonotrode; and a positioning device for positioning the connection element in relation to the substrate so that a contact foot of the connection element rests on a contact point of a conductor track of the substrate and is connected to the contact point by means of the sonotrode.

It is particularly preferred when the modulus of elasticity of the second partial abutment is between about 25 and about 100 N/mm².

It is further preferred when the first and the second partial abutment are mechanically connected to one another, preferably by means of a screw connection.

In this case, the second partial abutment can have a minimum thickness of at least about 0.2 cm, preferably at least about 1 cm.

It is particularly advantageous when the holding device is in the form of a mechanical clamping device and, as an alternative or in addition, is in the form of a pneumatic intake device.

Equally, it may be preferred when the contact point has a surface area of at least about 2 mm², preferably at least about 5 mm².

It is especially preferred when the second partial abutment has a hardness of from about Shore A 60 to about Shore D 80, preferably about Shore A 80 to about Shore A 95.

The second partial abutment is advantageously composed of a plastic, preferably a polyurethane, more preferably a polyurethane elastomer, and most preferably a polyether-based polyurethane elastomer.

In the inventive method for producing a power semiconductor module having a bottom element which is in the form of a substrate or in the form of a base plate with a substrate thereon, having a connection element, which is in particular composed of copper or a copper alloy, for electrical connection, wherein the connection element has a contact foot, the contact foot is connected to an associated contact point of a conductor track, which is in particular composed of copper or a copper alloy, of the substrate by welding.

It will be understood by one of ordinary skill in the art that the term “connection element” includes a plurality of connection elements, even connection elements with different functionalities, such as internally or externally routed load or auxiliary connection elements for example.

It may be preferred when the bottom element has at least a first portion which is pre-bent in the longitudinal direction. At the same time or as an alternative, it may be preferred when the bottom element has at least a second portion pre-bent in the transverse direction.

Other objects and features of the present invention will become apparent from the following detailed description considered in conjunction with the accompanying drawings. It is to be understood, however, that the drawings are designed solely for purposes of illustration and not as a definition of the limits of the invention, for which reference should be made to the appended claims. It should be further understood that the drawings are not necessarily drawn to scale and that, unless otherwise indicated, they are merely intended to conceptually illustrate the structures and procedures described herein.

### BRIEF DESCRIPTION OF THE DRAWINGS

In the drawings:

FIG. 1 shows a first embodiment of the inventive apparatus having an arranged substrate of a power semiconductor module;

FIG. 2 shows a second embodiment of the apparatus according to the invention having a base plate with a substrate of a power semiconductor module located on it;

FIG. 3 shows a plan view of and also a section through a base plate with substrates of a first power semiconductor module which is produced according to the invention located on it; and

FIG. 4 shows a plan view of and also a section through a base plate with substrates of a second power semiconductor module which is produced according to the invention located on it.

### DETAILED DESCRIPTION OF THE PRESENTLY PREFERRED EMBODIMENTS

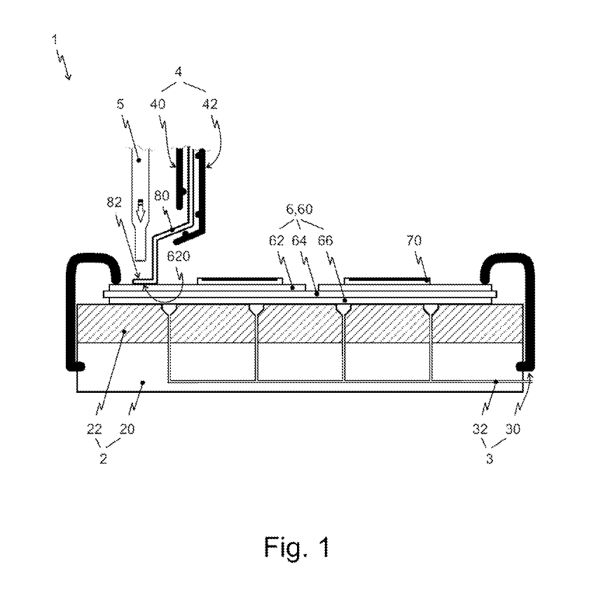

FIG. 1 shows a first embodiment of inventive apparatus 1. Apparatus 1 has an arranged substrate 60 of a power semiconductor module. FIG. 1 further shows an abutment 2 comprising first and second partial abutments 20, 22, respectively. First partial abutment 20 corresponds, preferably in its fundamental design, to an abutment which is customary in the art for welded connections, in particular ultrasonically welded connections. First partial abutment 20 is composed of a metal shaped body, preferably a steel body, here.

Second partial abutment 22 is connected to first partial abutment 20 in a force-fitting manner by means of screw connections which are customary in the art. Second partial abutment 22 forms, at its surface which is opposite from the first partial abutment 20, the bearing surface for an object which is to be connected by means of a welded connection, here a bottom element 6 of a power semiconductor module.

FIG. 1 also shows holding devices 3 for fixing this object which is to be welded or parts thereof. This figure shows two, here interacting, holding devices 3, here a clamping device 30 and also a pneumatic intake device 32, which together serve to hold the object on the surface of the second partial abutment 22 in a force-fitting manner.

These two embodiments are particularly advantageous when the object, the bottom element 6, itself does not have a sufficient degree of mechanical stability to be fixed only by means of one of the two holding devices 3.

Secondly, the two holding devices 30, 32 complement one another in terms of functionality in the case of any desired object.

The object which is arranged on the surface of second partial abutment 22 is a substrate 60, which is customary in the art, of a power semiconductor module here. Here, this substrate 60 comprises, by way of example only and without restricting the general nature of this description, an insulating-material body 64, for example an industrial ceramic with metal, preferably copper, laminations 62, 66 arranged on both main surfaces thereof. These copper laminations 62, 66 form conductor tracks 62 of the power semiconductor module in particular on that face of substrate 60 which is opposite from abutment 2.

Power semiconductor components 70 are customarily arranged on and electrically conductively connected to these conductor tracks 62 in the art. Further connections, not illustrated, connect power semiconductor components 70 to further conductor tracks 62 of substrate 60.

Here, the welded connection should be formed between one of conductor tracks 62 and a connection element 80 of the power semiconductor module. Here, connection element 80 is, by way of example only without restricting the general nature of this description, a load connection element for external connection of the power semiconductor module. Load connection element 80 has a contact foot 82 which is intended to be connected to an associated contact point 620 of conductor tracks 62 of substrate 60.

Load connection element 80, including contact foot 82, is designed as a metal shaped body, preferably composed of copper with a metal surface coating which is customary in the art and does not necessarily cover the entire surface thereof, particularly composed of silver or nickel.

Apparatus 1 has a two-part (40, 42) positioning device 4 for positioning load connection element 80 and, in particular, contact foot 82 in relation to contact point 620 of conductor track 62. Positioning device 4 positions contact foot 82 directly on contact point 620 or at a minimal distance from said contact point.

Apparatus 1 further has a sonotrode 5 for introducing the welding energy onto contact foot 82 of load connection element 80. To this end, sonotrode 5 is applied, in a manner indicated by the arrow, to that face of the contact foot 82 which is opposite from conductor track 62, and then moved in line with ultrasonic welding methods which are customary in the art, wherein frequencies in the range of between about 20 kHz and about 40 kHz are typically, but not necessarily, used.

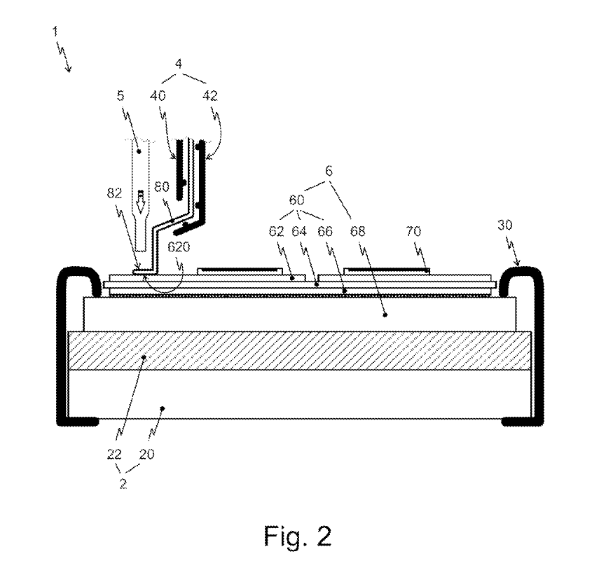

FIG. 2 shows a second embodiment of inventive apparatus 1 having an object which is to be connected, here a bottom element 6 of a power semiconductor module, which bottom element is in the form of a base plate 68 with a substrate 60 located thereon. Base plate 68 is designed in the form of a copper cuboid, as illustrated in a design of the base plate which is customary in the art for power semiconductor modules. Base plate 68 has a degree of mechanical stability which, in this embodiment of apparatus 1, renders a holding device 3 in the form of a pneumatic intake device superfluous. Therefore, holding device 3 is only in the form of a clamping device 30 here, without restricting the general nature, said clamping device exerting force directly on copper cuboid 68, but not on substrate 60, in accordance with this embodiment.

The object which is to be connected is identical to that according to FIG. 1, apart from copper cuboid 68, that is to say the base plate sits beneath substrate 60, here. Therefore, said object is a part of a power semiconductor module having a base plate.

Similarly to FIG. 1, a connection element 80 which, just like the associated positioning device 4 and sonotrode 5, is designed in accordance with FIG. 1 is connected to substrate 60.

Abutment 2 is likewise formed in accordance with FIG. 1 but, as mentioned, does not have a pneumatic holding device 32 here.

Since second partial abutment 22 is in the form of an elastic shaped body with a modulus of elasticity of between about 10 and about 500 N/mm² in both embodiments, bottom element 6, that is to say either substrate 60 or base plate 68 with substrate 60 arranged thereon, execute severely damped oscillation during the welding process. As a result, the welding process as such is more gentle and force peaks likewise have a damped effect on the actual welded connection. This firstly improves the quality of the connection and, at the same time, prevents preliminary damage to an object which is to be connected.

A protective welded connection of this kind is advantageous particularly in the case of substrates 60 of power semiconductor modules which comprise an industrial ceramic 64 with metal, preferably copper, laminations 62, 66 which are arranged on the two main surfaces and which form conductor tracks 62 at least on one face of the substrate. Copper laminations 62, 66 are connected to insulating-material body 64 in a manner which is customary in the art, inter alia, by means of a direct bonding method, wherein the adhesion force of the metal laminations 62, 66 on insulating-material body 64 is limited and, in the event of an excessively high action of force, can be overcome, at least locally, by a welding process which is customary in the art. During permanent operation of a power semiconductor module which is produced in this way, this often leads to premature breakdowns, that is to say to a reduced service life. Apparatus 1 according to the invention prevents this overloading of the connection of conductor tracks 62 to insulating-material body 64 during the welding process.

In the specific case of the two apparatus 1 according to FIGS. 1 and 2, the second partial abutment 22 is a cuboidal shaped body composed of polyether-based polyurethane elastomer with a thickness of 2±0.2 cm, a Shore A hardness of 80±5 and with a modulus of elasticity of 70±10 N/mm².

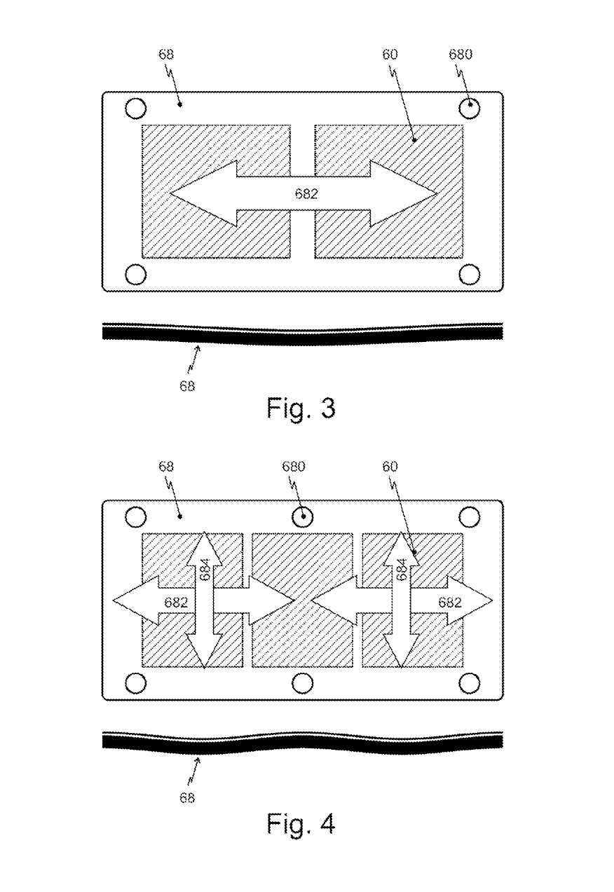

FIG. 3 shows a plan view of and also a section through a base plate 68 with two substrates 60 of a first power semiconductor module which is produced according to the invention located on it. In this case, base plate 68 has a recess 680 for mounting on a heat sink at each of its corners. In order to compensate for thermally induced stresses during operation, this base plate 68 has, in the longitudinal direction, a first portion 682 pre-bent so that a curvature directed toward a heat sink is formed near the center of base plate 68. A curvature of this kind is intended to be convex and be formed along the double-headed arrow here, wherein the maximum of the curvature lies roughly centrally with respect to the double-headed arrow.

FIG. 4 shows a plan view of and also a section through a base plate 68 with three substrates 60 of a second power semiconductor module which is produced according to the invention located on it. In this case, base plate 68 has three recesses 680 for mounting on a heat sink on each of its longitudinal sides. In order to compensate for thermally induced stresses during operation, this base plate has, pre-bent in the longitudinal direction, two first convex portions 682 and, perpendicular thereto, pre-bent in the transverse direction, two second convex portions 684.

The power semiconductor modules according to FIGS. 3 and 4 further have, in a manner not illustrated, a plurality of load connection elements for external electrical connection, wherein the respective load connection element has a contact foot which is connected to an associated contact point of a conductor track of the substrate 60 by welding. The respective load connection element is composed of copper, just like the base plate of the power semiconductor modules.

In the preceding Detailed Description, reference was made to the accompanying drawings, which form a part of his disclosure, and in which are shown illustrative specific embodiments of the invention. In this regard, directional terminology, such as “top”, “bottom”, “left”, “right”, “front”, “back”, etc., is used with reference to the orientation of the Figure(s) with which such terms are used. Because components of embodiments can be positioned in a number of different orientations, the directional terminology is used for purposes of ease of understanding and illustration only and is not to be considered limiting.

Additionally, while there have been shown and described and pointed out fundamental novel features of the invention as applied to a preferred embodiment thereof, it will be understood that various omissions and substitutions and changes in the form and details of the devices illustrated, and in their operation, may be made by those skilled in the art without departing from the spirit of the invention. For example, it is expressly intended that all combinations of those elements and/or method steps which perform substantially the same function in substantially the same way to achieve the same results are within the scope of the invention. Moreover, it should be recognized that structures and/or elements and/or method steps shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

What is claimed is:

1. Apparatus for connecting a connection element having a contact foot to a conductor track of a substrate, the conductor track having a contact point, the connection between the connection element and the substrate being established by welding, wherein the apparatus comprises:
a bottom element;
an abutment for positioning said bottom element, said abutment including:
a first partial abutment having a metal shaped body with a modulus of elasticity of between about 50 and about 300 kN/mm²; and
a second partial abutment having an elastic shaped body with a modulus of elasticity of between about 10 and about 500 N/mm², and wherein said bottom element rests on said second partial abutment;
a holding device for fixing said bottom element on said abutment;
a positioning device for positioning the connection element in relation to the substrate so that the contact foot rests on the contact point; and
a sonotrode for connecting the contact foot to the contact point.

2. The apparatus of claim 1, wherein said bottom element is the substrate.

3. The apparatus of claim 1, wherein said bottom element is a base plate having the substrate located thereon.

4. The apparatus of claim 1, wherein said bottom element rests exclusively on said second partial abutment.

5. The apparatus of claim 1, wherein said modulus of elasticity of said second partial abutment is between about 25 and about 100 N/mm².

6. The apparatus of claim 1, wherein said first and said second partial abutments are mechanically connected to one another.

7. The apparatus of claim 6, wherein said first and said second partial abutments are mechanically connected to one another by a screw connection.

8. The apparatus of claim 1, wherein said second partial abutment has a minimum thickness of at least about 0.2 cm.

9. The apparatus of claim 8, wherein said second partial abutment has a minimum thickness of at least about 1 cm.

10. The apparatus of claim 1, wherein said holding device is in the form of at least one of a mechanical clamping device and a pneumatic intake device.

11. The apparatus of claim 1, wherein said contact point has a surface area of at least about 2 mm².

12. The apparatus of claim 11, wherein said contact point has a surface area of at least about 5 mm².

13. The apparatus of claim 1, wherein said second partial abutment has a hardness of between about Shore A 60 to about Shore D 80.

14. The apparatus of claim 13, wherein said second partial abutment has a hardness of between about Shore A 80 to about Shore A 95.

15. The apparatus of claim 1, wherein said second partial abutment is composed of a plastic.

16. The apparatus of claim 15, wherein said second partial abutment is composed of a polyurethane.

17. The apparatus of claim 16, wherein said second partial abutment is composed of a polyurethane elastomer.

18. The apparatus of claim 17, wherein said second partial abutment is composed of a polyether-based polyurethane elastomer.

19. A method for producing a power semiconductor module having a bottom element with a contact point and a connection element with a contact foot, the method comprising the steps of:
providing an abutment for positioning the bottom element, said abutment including:
a first partial abutment having a metal shaped body with a modulus of elasticity of between about 50 and about 300 kN/mm²; and
a second partial abutment having an elastic shaped body with a modulus of elasticity of between about 10 and about 500 N/mm²;
positioning said bottom element on said second partial abutment;
fixing said bottom element on said abutment;
positioning the connection element in relation to the bottom element so that the contact foot rests on the contact point; and
welding the contact foot to the contact point.

20. The method of claim 19, wherein said connection element is composed of at least one of copper and a copper alloy.

21. The method of claim 19, wherein said conductor track is composed of at least one of copper and a copper alloy.

22. The method of claim 19, wherein said bottom element has at least a first portion pre-bent in the longitudinal direction.

23. The method of claim 19, wherein said bottom element has at least a second portion pre-bent in the transverse direction.

24. The method of claim 19, wherein said welding is ultrasonic welding.
